(19) United States
(12) Patent Application Publication
(10) Pub. No.: US 2011/0266624 A1
(43) Pub. Date: Nov. 3, 2011

(54) ELECTROSTATIC DISCHARGE PROTECTION HAVING MULTIPLY SEGMENTED DIODES IN PROXIMITY TO TRANSISTOR

(75) Inventors: Charvaka DUVVURY, Plano, TX (US); Yen-Yi LIN, Plano, TX (US)

(73) Assignee: TEXAS INSTRUMENTS INCORPORATED, Dallas, TX (US)

(21) Appl. No.: 12/771,114

(22) Filed: Apr. 30, 2010

(51) Int. Cl. H01L 27/06; H01L 21/8234

(52) U.S. Cl. 257/360; 438/237; 361/56; 257/E27.016; 257/E21.616

(57) ABSTRACT

An ESD protection device for an I/O pad (401); the device comprising a MOS transistor (420) having at least one elongated source region (422) and at least one elongated drain region (421) in a substrate (400) of first conductivity, the length (420a) of the source and drain regions oriented in a direction, the source tied to ground potential (430); a diode having an area including at least one elongated anode region and at least one elongated cathode region in a well of opposite conductivity, the lengths of the anode and cathode regions oriented in the same direction as the transistor regions; the diode area and the well divided normal to the lengths of the anode and cathode regions into two portions (anode portions 411x, 411y, cathode portions 412x, 412y, length portions 410x, 410y, well portions 440x, 440y); and the anode portions connected to the I/O pad, and the cathode portions connected to the transistor drain.

### FIELD OF THE INVENTION

The present invention is related in general to the field of semiconductor devices and processes, and more specifically to the structure, layout, and fabrication method of low capacitance electrostatic discharge protection devices having multiply segmented diodes in close proximity to, and on two or more sides of transistors.

### DESCRIPTION OF RELATED ART

Integrated circuits (ICs) may be severely damaged by electrostatic discharge (ESD) events. A major source of ESD exposure to ICs is from the human body (described by the “Human Body Model”, HBM); the discharge of the human body generates peak currents of several amperes to the IC for about 100 ns. A second source of ESD is from metallic objects (described by the “Machine model”, MM); it can generate transients with significantly higher rise times and current levels than the HBM ESD source. A third source is described by the “charged device model” (CDM), in which the IC itself becomes charged and discharges to ground in rise times less than 500 ps.

ESD phenomena in ICs are growing in importance as the demand for higher operating speed, smaller operating voltages, higher packing density and reduced cost drives a reduction of all device dimensions. This generally implies thinner dielectric layers, higher doping levels with more abrupt doping transitions, and higher electric fields—all factors that contribute to an increased sensitivity to damaging ESD events.

One common scheme to protect an input/output (I/O) pad against ESD failure uses metal-oxide-semiconductor (MOS) ICs, such as nMOS transistor with its drain connected to the pin to be protected and its source tied to ground, and relies on the mode of a parasitic bipolar transistor (the source acts as the emitter, the drain as the collector, and the bulk semiconductor as the base) during an ESD event to provide a low impedance current path to ground. The protection level or failure threshold can be set by varying the nMOS device width.

The current carrying capability of the device is limited by thermal effects in the avalanching collector depletion layer. A number of effects (such as the increase of intrinsic carrier concentration, a reduction of carrier mobility, a decrease in thermal conductivity, and a lowering of the potential barrier for tunnel currents) contribute to the onset of thermal runaway, the second (thermal) breakdown. The reduction of the impact ionization current is offset by the thermal generation of carriers. Second breakdown, initiated in a device under stress as a result of self-heating, is characterized by the trigger current Iₜ₂, which is very sensitive to the device design, especially the doping profiles; it results in junction melting and in an irreversible increase in leakage currents.

Another common protection scheme used in MOS ICs employs a first diode with its cathode connected to the power (V_{DD}) terminal for positive ESD stress and its anode connected to the I/O pad to be protected. The diode has to be made of large area, since the on-resistance of the diode determines the effectiveness. A second diode has its anode connected to ground potential (V_{SS}) for negative ESD stress and its cathode to the pad.

A variant of this scheme still uses the first diode for positive ESD stress, but employs a MOS transistor in place of the second diode, with the drain of a MOS transistor tied to the pad and the source tied to ground potential; the gate is typically also connected to ground through a resistor. For negative ESD stress, the parasitic diode of the transistor, formed by the pad as cathode and V_{SS} as anode, offers protection. In many devices, the semiconductor substrate is p-type so that the diode is built in an n-well as a pn diode and the transistor is an nMOS transistor. The parasitic bipolar pnp transistor of the diode pumps current into the substrate of the transistor, triggering it as an effective npn device. The efficiency of this protection depends on the capacitance associated with the V_{DD} terminal; if it were too small, the vertical pnp shuts off before the HBM event, causing premature failure in the MOS transistor.

Yet another known ESD protection scheme applies to semiconductor devices integrating RF, analog and digital circuits on the same substrate using a so-called fail-safe design, which do not allow a diode between the I/O pad and V_{DD}. In these ESD protection devices, the I/O pad is connected to the anode of a forward biased diode located in a well with conductivity opposite to the substrate conductivity. The diode cathode is tied to the drain of an MOS transistor formed in the substrate; source and gate of the MOS transistor are connected to ground potential, V_{SS}. The MOS transistor forms a parasitic bipolar npn transistor with the collector at the drain, the emitter at the source, and the base at the resistive substrate. The protection concept is sometimes referred to as diode-isolated MOS concept.

The ESD trigger current Iₜ₂ in the diode-isolated MOS protections has typically two components, which follow different routes from the pad to ground: One current path is through the forward biased diode and the parasitic npn transistor, and the other current path through a parasitic silicon-controlled rectifier (SCR) formed by the diode anode as SCR anode, the well, the substrate, and the source of the MOS transistor as the SCR cathode. The SCR is thus formed by the vertical pnp from the n-well diode with the lateral npn of the nMOS transistor. As mentioned above, in order to achieve low diode on-resistance and sufficient substrate pumping to turn on the MOS transistor, the diode has to have a large area.

### SUMMARY OF THE INVENTION

Applicants recognized that the ESD trigger currents Iₜ₂ of protection devices in advanced semiconductor products of the wireless, RF, fail-safe, USB, IEC, and related families becomes unacceptably small, mostly because of the small size of these products and the relentless trend towards more scaling. In addition, applicants found that the protection devices cannot be relied upon for achieving uniform trigger and thus efficient protection, when the layouts of diode and transistor are done in random fashion; while the layout goal of minimum capacitive loading remains unchanged, the multitude of different I/O functions requires different layout specifications to become compatible with the respective pin specification. In particular, it has to be avoided that in some layouts of the diode in relation to the transistor, only insufficient substrate pump effects are observed. Furthermore, applicants recognized that if a way could be found to increase the Iₜ₂ density (A/μm) without initiating second breakdown, the same magnitude of Iₜ₂ could be achieved with smaller consumption of semiconductor real estate.

Experiments have shown that large area diodes are needed, when they are placed near one side of the nMOS transistor, to achieve high trigger currents Iₜ₂. Applicants discovered that not only the Iₜ₂ portion through the diode in series with the npn transistor is restricted to the surface-near region of the diode, but also the Iₜ₂ portion of the SCR, resulting in a quick heating of the surface-near region. On the other hand, the bulk region of the diode carries only little current and is thus under-utilized as a heat sink, keeping Iₜ₂ at low values unless the diode area is further enlarged.

Applicants solved the problem of increasing the trigger current Iₜ₂ while keeping the diode area constant by splitting the diode area into two halves, then leaving one half area in its original location while positioning the hitherto under-utilized diode half area symmetrically on the opposite side of the nMOS transistor. In this new position, the second, hitherto under-utilized diode half area carries its full share of the SCR portion of Iₜ₂, thus balancing the trigger current flow, while simultaneously participating fully as an additional heat sink. The resistance of the trigger current is reduced, allowing higher Iₜ₂ values without a need for increasing the total diode area and a risk of thermal runaway. While achieving this, the net capacitance is conserved.

Applicants further found that an additional increase of Iₜ₂ is obtained when the distances between the two n-wells of the diode halves and the transistor diffusions are reduced to the closest proximity free of electrical shorts. By reducing the distances, the contribution of the semiconductor substrate to the electrical resistance of the bipolar trigger current portion can be reduced, allowing more current before heating and thermal runaway.

Integrated circuits in p-type silicon fabricated with 65 nm CMOS silicided technology included ESD protection devices with 1.8 V multi-finger nMOS transistors of 8×20 μm size and 0.18 μm gate length; the diodes in the n-wells had 140 μm perimeter. While the devices fabricated only with a transistor but without a diode achieved only an Iₜ₂ of 0.6 A (or 3.6 mA/μm), devices with a diode aligned along a transistor side at 5 μm distance between n-well and transistor fingers exhibited an Iₜ₂ of 1.3 A (or 8.3 mA/μm). Splitting the diode area into two halves and positioning the halves at opposing sides of the transistor at a distance of 5 μm, increased the trigger current to 1.6 A (or 9.8 mA/μm). Reducing the distance between n-well and transistor fingers to 1.2 μm produced an Iₜ₂ of 1.9 A (or 12.1 mA/μm).

It is a technical advantage that the concept of dividing the diode area can be extended to applications, where the still finer slices of diode area are placed on three or four sides of the MOS transistor. It is another technical advantage that the concept can be applied to drain-extended MOS transistors.

It is a further technical advantage that the concept of the invention is applicable to I/Cs in p-type semiconductor bulk conductivity and thus to protection devices with nMOS transistors, as well as to I/Cs in n-type bulk conductivity and thus to protection devices with pMOS transistors.

### BRIEF DESCRIPTION OF THE DRAWINGS

FIG. 1 is a schematic diagram of an ESD protection device based on the diode isolated grounded-gate nMOS structure including a diode in series with an MOS transistor.

FIG. 2 illustrates schematically the two contributions to the ESD trigger current flowing through the diode isolated grounded-gate nMOS ESD protection device: The contribution through the diode in series with the turned-on npn MOS transistor, and contribution through the parasitic silicon-controlled rectifier.

FIG. 3 depicts a schematic top view of the layout of an nMOS transistor together with a single pn diode including the approximate region of temperature increase due to current concentration.

FIG. 4 is a schematic top view of the layout of an nMOS transistor together with the balanced positioning of two pn diode halves according to the invention.

FIG. 5 shows a schematic cross section of diodes in an n-well in p-type substrate semiconductor, the diodes tied in series with nMOS transistors to facilitate the balanced formation of protective parasitic bipolar transistors and parasitic SCRs according to the invention.

FIG. 6 depicts exemplary measurements of current (in A) as a function of voltage (in V) in various ESD protection devices, highlighting the layout superiority of split diodes in proximity to a MOS transistor according to the invention.

### DETAILED DESCRIPTION OF THE PREFERRED EMBODIMENTS

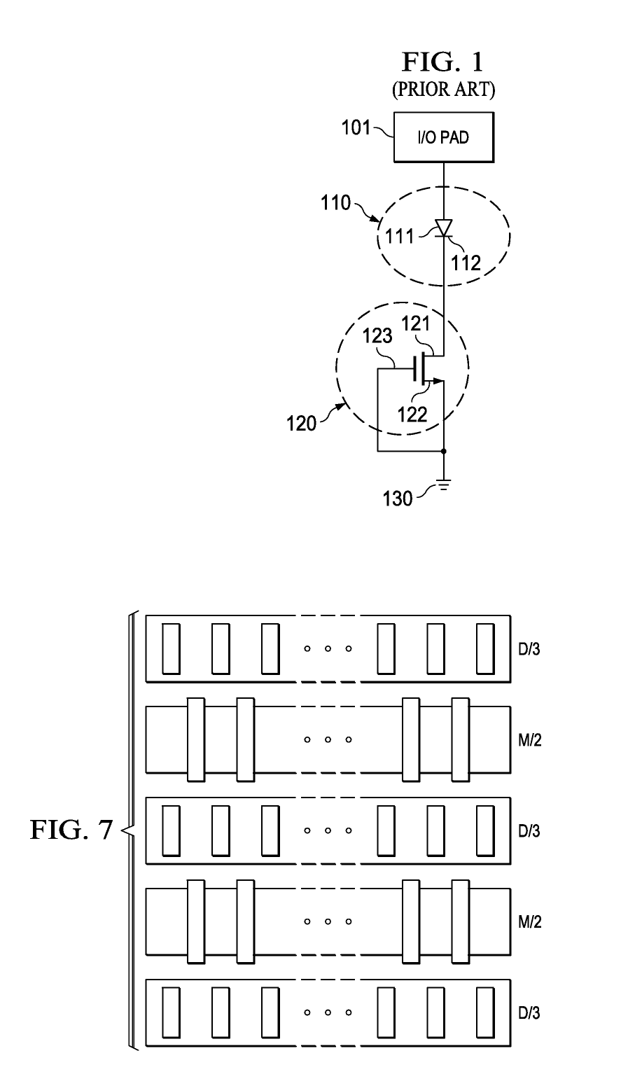

FIG. 1 shows the block diagram of the concept referred to as the diode isolated grounded-gate MOS concept for protecting fail-safe, RF, wireless, and other advanced ICs in a semiconductor device against ESD events. The input/output (I/O) pad 101 to be protected is in series with the forward biased diode 110 and MOS transistor 120 to ground potential 130. Pad 101 is connected with the anode 111 of diode 110; the cathode 112 of the diode is tied to the drain 121 of MOS transistor 120.

The integrated circuit (I/C) and the device for ESD protection are fabricated in a semiconductor substrate. The term “substrate” refers herein to the starting semiconductor wafer, which, in present manufacturing, typically has p-type doping. For clarity, this case is also selected as the basis for the following discussions. For many applications, the first conductivity type referenced above is p-type and the opposite conductivity type is n-type. With this selection, the semiconductor substrate mentioned above is a p-type substrate, the MOS transistor an nMOS transistor, the diode a pn-, and the silicon-controlled rectifier a pnpn-SCR. It should be stressed, however, that the invention and all description also cover the case where the substrate has n-type doping. Frequently, but not necessarily, an epitaxial layer of the same conductivity type as the substrate has been deposited over the substrate; in this case the term “substrate” refers to epitaxial layer plus starting semiconductor. For preferred p-type substrates, the sheet resistance range is from about 200 to 500 Ω/; the selection of the substrate resistivity and sheet resistance determines the size of the substrate resistance.

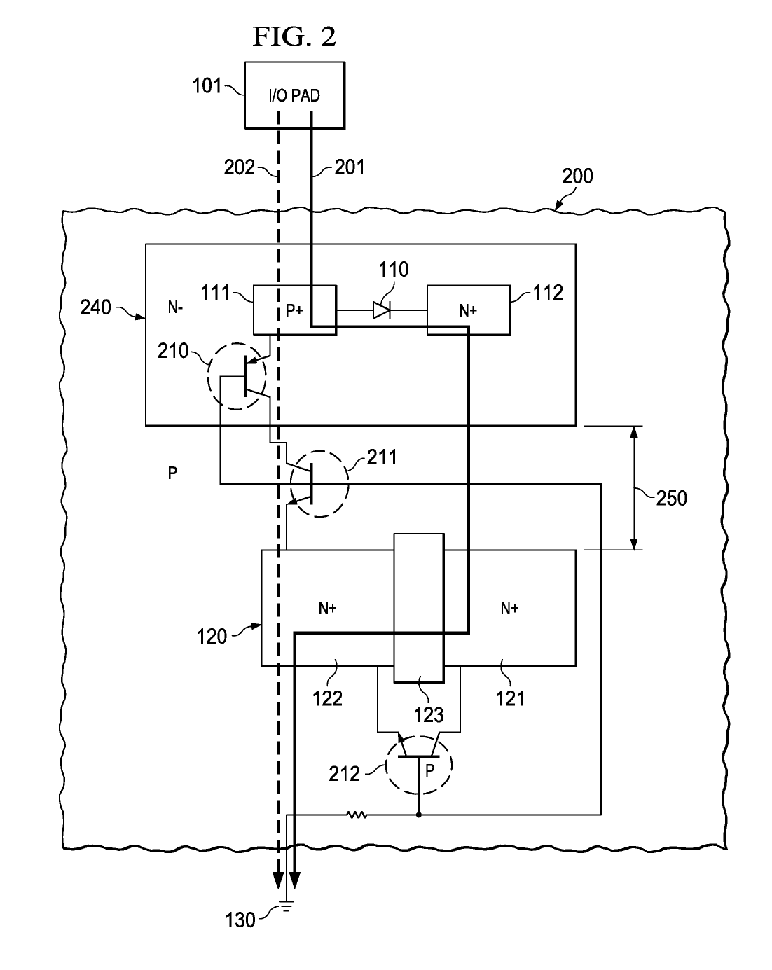

The circuit block diagram of FIG. 1 of the protection device is displayed in FIG. 2 as a schematic top view of the electrical components together with the portions of the ESD discharge current flows. The selection of the electrical conductivities is exemplary. The p-type semiconductor substrate is designated 200 and the n-well is designated 240; I/O pad 101 and ground potential 130 are considered external to semiconductor substrate 200. With the substrate p-type, diode 110 is fabricated in an n⁻-well 240, and MOS transistor 120 is an nMOS transistor, preferably a multi-finger transistor. The n⁺ drain region 121 is connected to diode cathode 112, and the n⁺ source region 122 is connected to ground potential (V_{SS}) 130. The metallization of gate 123 is also tied to ground (not shown in FIG. 2). During an ESD event, one portion of the protection relies on the mode of a parasitic bipolar transistor 212 formed by the MOS transistor to provide a low impedance current 201 to ground; source 122 acts as an emitter, drain 121 as a collector, and the resistive substrate 200 as the base. The protection level or failure threshold (trigger current Iₜ₂) can be set by varying the nMOS transistor width; the protection level thus depends on the layout style. Under stress conditions, the dominant current conduction path between the protected pin and ground involves the parasitic bipolar transistor 212 of that nMOS transistor 120. This parasitic bipolar transistor operates in the snapback region under pin positive with respect to ground stress events. The concept also works for drain-extended nMOS transistors. The concept has been applied to low-capacitance ESD protection where the substrate pump from the vertical pnp transistor (inherent in the diode) provides uniform trigger for the MOS transistor. In these applications, the layout of the diode in relation to the MOS transistor is arbitrary, and the diode is generally placed at some distance next to a side of the MOS layout. In FIG. 2, the complete discharge current is shown as conduction path 201 from pad 101 through anode 111, well 240, cathode 112, drain 121, substrate 200 under gate 123, and source 122 to ground 130.

In order to determine the nMOS transistor 120 layout for the assumption that the complete ESD current is to be discharged following the conduction path 201 in FIG. 2, a calculation shows that the discharge of the 4 kV of the HBM requires, at the empirical HBM performance of 10 V/μm for a substrate-pumped transistor, an active transistor length of 400 μm. Source and drain regions are designed to typically have individual lengths of 40 μm; consequently, 10 gates are needed. If transistor 120 were to handle the ESD event as a substrate-pumped MOS clamp, the transistor area would result in a capacitance of about 500 fF. Based on these layout selections, transistor 120 in series with the forward biased diode 110 is providing a discharge path to ground for an ESD current.

For discharging an ESD current to ground, FIG. 2 illustrates in addition to the path 201 of the parasitic bipolar transistor action of the nMOS transistor the path 202 of a parasitic silicon controlled rectifier (SCR) action. In order for path 202 to accept a significant portion of the ESD discharge current, the n-well 240 is to be laid out so that it is positioned in proximity to the regions of the MOS transistor. In FIG. 2, the close proximity is indicated by distance 250. For many protection devices, distance 250 is preferably between 1 and 5 μm. In the well 240 is at least one diode 110, its anode region 111 of the first conductivity type connected to I/O pad 101 and its cathode region 112 of the opposite conductivity type, connected to transistor drain 121. The layout is executed so that the diode-anode 111 is positioned in proximity to, and aligned with, the source region 122 of the MOS transistor, and the diode-cathode 112 is positioned in proximity to, and aligned with, the drain region 121. For a selected diode resistivity, the diode area is determined so that the diode on-resistance is low enough to allow sufficient current to flow through the diode to provide reliable substrate pumping for turning on the MOS transistor. Consequently, for many protection devices, the diode area is approximately a third of the MOS transistor area.

Based on the proximity layout of the transistor and diode regions and the electrical connections, a localized parasitic silicon-controlled rectifier (SCR) pnpn is created. In the schematic FIG. 2, the parasitic pnpn SCR is indicated by its pnp transistor portion 210 and its npn transistor portion 211, interconnected by solid lines. It comprises an SCR-anode formed by the diode-anode 111; a first base region formed by the well; a second base region formed by the substrate; and an SCR-cathode formed by the transistor source 122. The I/O pad 101 becomes the SCR-anode, and ground potential 130 (V_{SS}) becomes the SCR-cathode. The parasitic SCR offers efficient ESD protection because it is operable to distribute an ESD current at low voltages. A further layout advantage of the embodiment of FIG. 2 is the fact that the gate 123 of MOS transistor 120 does not need a resistor to ground potential 130, since the successful ESD protection of FIG. 2 does not fully depend on an efficient npn device with additional circuit connections.

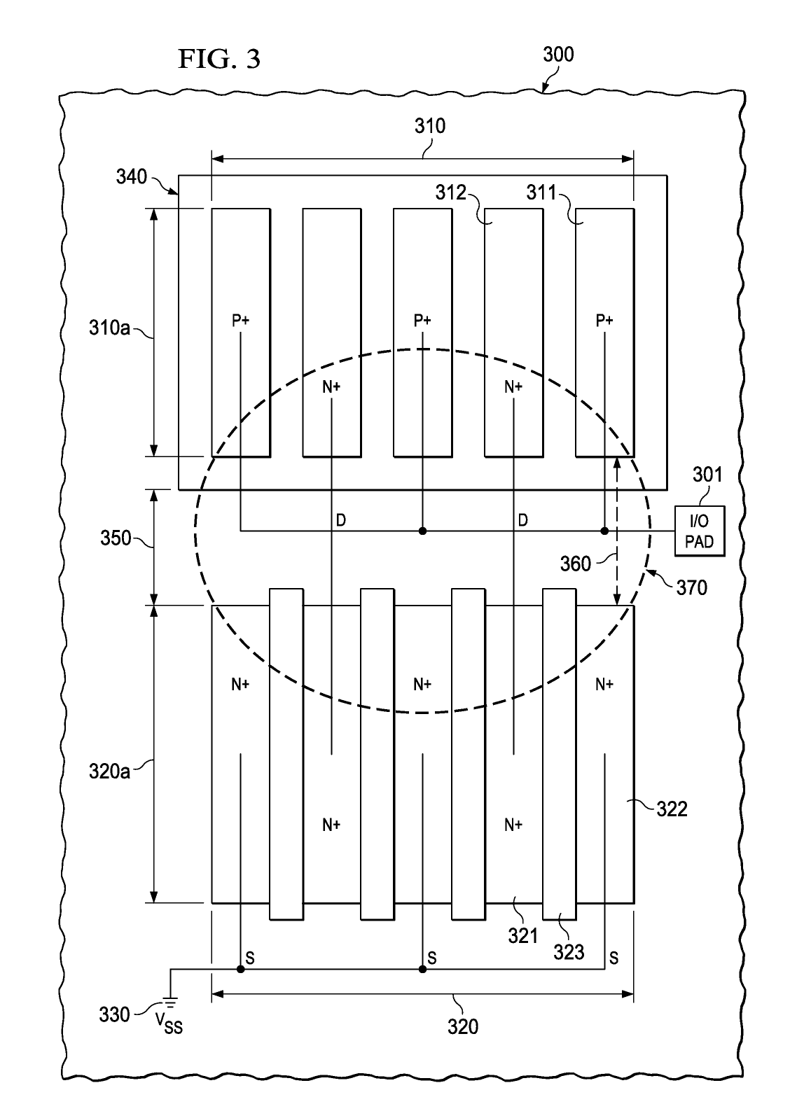

In the example illustrated in FIG. 3 for protecting I/O pad 301, diode 310 in series with MOS transistor 320 are designed together as aligned multi-finger components in a one-on-one layout based on the resistivity of the semiconductor substrate 300. Diode 310 has interdigitated p⁺ and n⁺ regions, and transistor 320 has multi-finger n⁺ regions, separated by gate regions 323. Diode anode and cathode have the length 310a, which is the same as the length 320a of the transistor regions. It should be stressed, however, that in other diode designs, region length 310a may be shorter than transistor region length 320a. In the example of FIG. 3, the lengths 310a and 320a are about 40 μm. Each n⁺ region of the transistor is aligned with a respective region of the diode, alternatively a p⁺ region and an n⁺ region. As an example, n⁺ region 322, serving as a source region and tied to ground potential V_{SS} 330, is aligned with p⁺ region 311, serving as diode anode region and tied to I/O pad 301. The alignment is indicated in FIG. 3 by dashed arrow 360. Based on this alignment, p⁺ region 311, and thus the I/O pad, becomes the SCR anode, and n⁺ region 322, and thus ground V_{SS} 330, becomes the SCR cathode. Transistor n⁺ region 321, serving as a drain region, is tied to and aligned with diode n⁺ region 312. In exemplary FIG. 3, the SCR conduction paths resulting from the layout alignment are repeated two more times across the multi-finger components; in other production devices may be many more repetitions. The alignment of the diode anode and cathode regions with the respective transistor n⁺ regions is one of the enablers for the conduction paths of the SCR.

The other enabler to trigger the SCR for the ESD discharge is the distance 350 for close proximity of well 340 and transistor n⁺ regions. In the example of FIG. 3, distance 350 is about 2 to 5 μm. The discharge the 4 kV of the HBM requires, at the empirical HBM performance of 100 V/μm for an SCR, an active transistor length of 40 μm. With source and drain length 320a of typically 40 μm, only one gate as a minimum can be used. The transistor area for this length results in a capacitance as low as about 100 fF.

The distribution of the total ESD discharge current between the current portion along the diode-plus-npn path and the current portion along the SCR path can be shifted from 100% along the diode-plus-npn path to 100% along the SCR path by design considerations such as discussed in conjunction with FIG. 3. All distribution ratios may be considered, such as 50% current flow along the diode-plus-npn path and 50% along the SCR path. The SCR path is generally considered more efficient, because it better utilizes the available substrate material for routing the current compared to the more surface-near routing of the diode-plus-npn path.

The flows of the ESD discharge currents along the SCR path and along the diode-plus-npn path create thermal energy along the paths and cause an increase of temperature in the affected semiconductor material. Thermal measurements have demonstrated considerably steeper temperature increases in the region of proximity between the diode and the MOS transistor; the region is schematically outlined by dashed contours 370 in FIG. 3. The temperatures outside the contours remain at a lower level. These data indicate that especially the SCR current is not equally distributed and consequently does not fully utilize the available substrate semiconductor material as a heat sink. The portion of the semiconductor substrate inside the contour carries a heavier share in the current conduction and as a heat sink and thus heats up faster, while the substrate portions outside the contour participate less in the current conduction and as heat sinks.

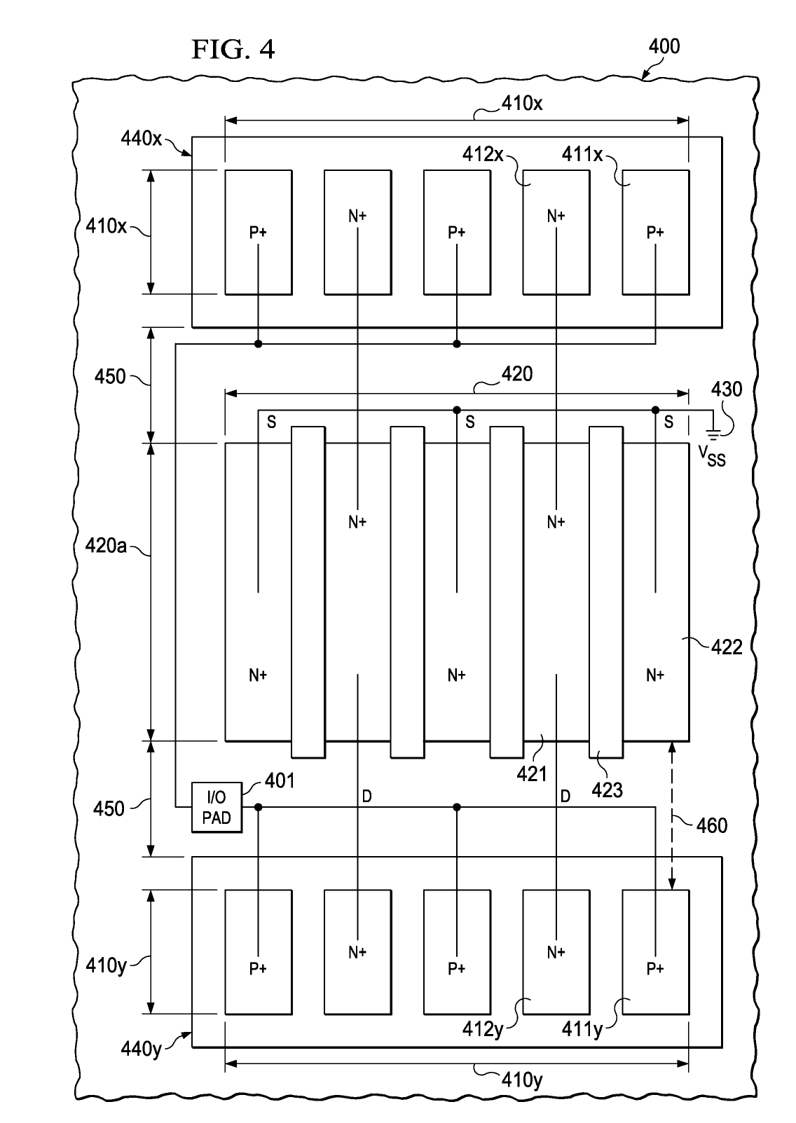

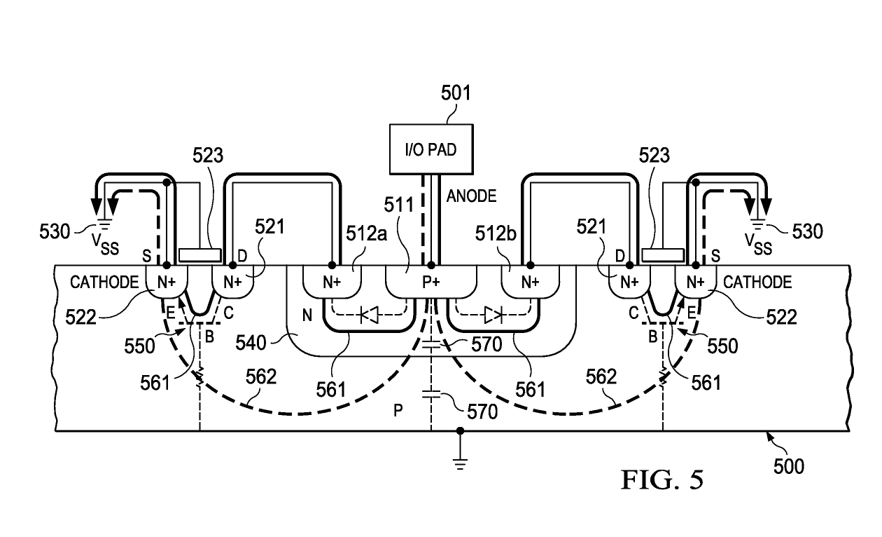

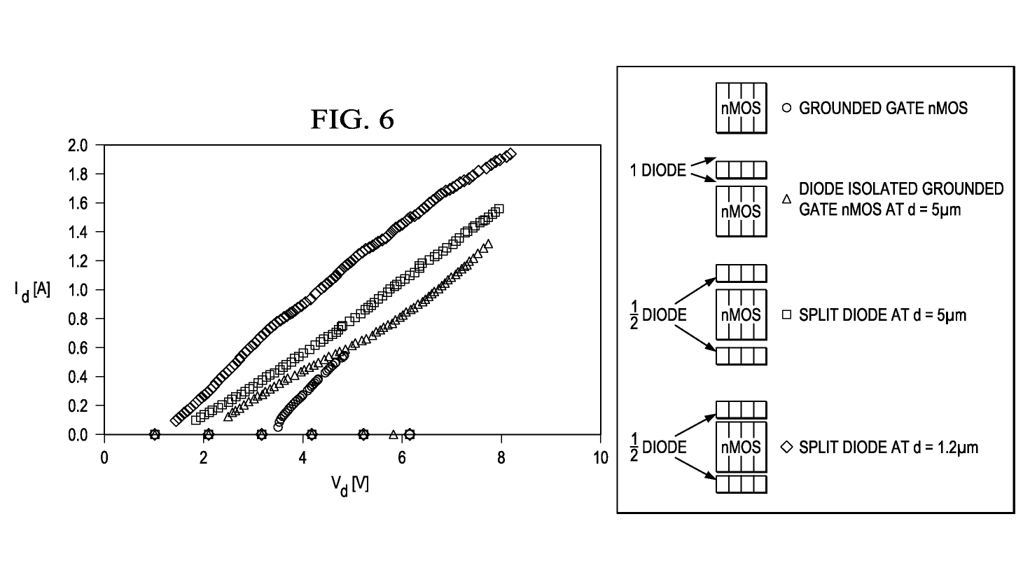

In order to remedy this unequal current conduction and to take full advantage of all the available semiconductor substrate as a heat sink, the area of the diode and the well is divided normal to the length 310a of the anode regions 311 and cathode regions 312 into two portions. The diode area portions may be approximately equal with respect to size and shape, or they may be different. The portions are positioned symmetrically at opposite sides of the MOS transistor, preferably at the closest proximity free of electrical shorts between the well and the transistor regions. The diode portions positioned at two sides of the MOS transistor double the discharge paths for the ESD currents; they also double the semiconductor substrate volume efficiently utilized as heat sinks. As a consequence, the temperature increase caused by the discharge currents is postponed so that the value of the trigger current Iₜ₂ is increased. The resulting layout of the diode portions and the MOS transistor for improved ESD protection is discussed in FIG. 4; the resulting flows of ESD discharge currents are exemplified in FIG. 5; and examples for increased trigger currents are displayed in FIG. 6.

In the example illustrated in FIG. 4 for protecting I/O pad 401, the diode portions 410x and 410y are placed at opposite sides of MOS transistor 420 and electrically connected in series with MOS transistor 420. The transistor regions have the length 420a. Each diode portion 410x and 410y has its own well portion 440x and 440y, respectively. Diode portions 410x and 410y are designed together with MOS transistor 420 as aligned multi-finger components in a one-on-one layout based on the resistivity of the semiconductor substrate 400. Diode portions 410x and 410y have segmented p⁺ and n⁺ regions, and transistor 420 has multi-finger n⁺ regions, separated by gate regions 423. In the example of FIG. 4, the diode portions 410x and 410y are equal in size and shape; consequently, the lengths 410x of the anodes and cathodes in one diode half are equal to the lengths 410y of the anodes and cathodes in the other diode half. It should be pointed out that in some devices the diode area may be divided into portions of unequal size and shape.

Each n⁺ region of the transistor is aligned with a respective region of the diode portions, alternatively a p⁺ region and an n⁺ region. As an example, n⁺ region 422, serving as a source region and tied to ground potential V_{SS} 430, is aligned with μ p⁺ regions 411x as well as 411y, serving as diode anode regions and tied to I/O pad 401. The alignment is indicated in FIG. 4 by dashed arrow 460. Based on this alignment, p⁺ regions 411x and 411y, and thus the I/O pad, become the anodes of SCR branches, and n⁺ region 422, and thus ground V_{SS} 430, become the cathodes of SCR branches. Transistor n⁺ region 421, serving as a drain region, is tied to and aligned with diode n⁺ regions 412x and 412y. In exemplary FIG. 4, the SCR conduction paths resulting from the layout alignment are repeated across the multi-finger components, but are oriented in opposite directions relative to the MOS transistor. The alignment of the diode anode and cathode regions with the respective transistor n⁺ regions is one of the enablers for the conduction paths of the SCR.

The other enabler to trigger the SCR for the ESD discharge is the distance 450 for close proximity of wells 440x and 440y and transistor n⁺ regions. In preferred embodiments, distance 450 is selected at the closest possible proximity free of electrical shorts. Dependent on the technology used for fabrication, distance 450 may be between about 1 to 5 μm. The data presented in FIG. 6 show trigger currents Iₜ₂ for a distance of 5 μm and of 1.2 μm and demonstrate the significant improvement of trigger current Iₜ₂ at the smaller distances.

In order to emphasize the heat sink capability of the substrate material for the SCR path, FIG. 5 illustrates schematically the manner of the discharge current flows through the substrate in an ESD protection device including a diode and a MOS transistor connected in series and physically divided according to the methodology discussed in conjunction with FIG. 4. The protection device for I/O pad 501 in FIG. 5 has the semiconductor substrate 500 selected with p-type conductivity and the well with n-type conductivity, but the following considerations are equally valid for opposite conductivities. In well 540 is a diode divided into two portions with a p⁺ region 511 as the diode anode and two n⁺ regions 512a and 512b serving as diode cathodes. The divided diode is forward biased; diode anode 511 is connected to pad 501 and cathodes 512a and 512b are each tied to an n⁺ region 521, which act as the drains of MOS transistors. The n⁺ regions 522 of the transistor sources are tied to ground potential 530; the gates 523 of the MOS transistors are also connected to ground 530.

FIG. 5 shows in dashed outline the parasitic bipolar npn transistors 550 formed by the MOS transistors through the substrate to ground. The MOS transistor sources 522 form the emitters of the parasitic bipolar transistors, the drains 521 form the collectors, and the resistive substrate 500 forms the bases. As the parasitic silicon-controlled-rectifier, the diode anode 511 forms the SCR anode, the well 540 the n-base, the substrate 500 the p-base, and the grounded MOS transistor sources 522 the SCR cathode.

The portions 561 of the ESD current discharging through the combination of diode and parasitic npn transistor are indicated in FIG. 5 as the dashed current flow through device zones close to the surface. Due to this surface-near current flow, not much semiconductor material becomes involved as heat sink. Consequently, these surface-near zones heat up relatively fast; preferably, these portions of the ESD current should thus not represent the major fraction of the total ESD discharge current.

On the other hand, the portions 562 of the ESD current discharging through the parasitic SCR, indicated as dashed flow in FIG. 5, extend through the bulk of the substrate. Due to the flow through the bulk, much semiconductor material becomes involved as heat sink. Consequently, these bulk zones heat up relatively slowly; preferably, these portions of the ESD current should thus represent the major fraction of the total ESD discharge current. As FIG. 5 emphasizes, the layout solution of the invention to offer the SCR discharge current two routes instead of only one route through the bulk material, doubles the benefit of the substrate heat sink to slow the temperature rise; doubling the routes through the heat sink thus allows a higher trigger current to flow through the protection device.

It is a technical advantage of the layout used by the invention that the discharge current flows are symmetrical relative to the layout of the diode and transistor components. With this symmetry, a segmented layout of the diode regions, aligned with the multi-finger design of the MOS transistor, can be best utilized. The advantage also is applicable for drain-extended MOS transistor.

FIG. 6 is a plot of data obtained for discharge current I_{d} (in A) as a function of discharge voltage V_{d} (in V) in a variety of protection devices fabricated in p-type silicon substrates. The production ICs were fabricated with 65 nm CMOS silicided technology; the protection devices had 1.8 V multi-finger nMOS transistors of 8×20 μm size and 0.18 μm gate length; the diodes in the n-wells had 140 μm perimeter. The current-voltage characteristics of FIG. 6 are dominated by the parasitic SCR; they can in principle be constructed by combining the I-V characteristic of an nMOS transistor (resistive slope) with the I-V characteristic of a component SCR. Special attention for the data of FIG. 6 is warranted by the holding voltage V_{H} at the start point of the resistive slope and the trigger current Iₜ₂ at end point of the resistive slope.

Curve “a” was measured using a protection device including only a multi-finger nMOS transistor with grounded gate, thin gate oxide, and geometrical dimensions similar to the ones quoted above (no diode). The holding voltage V_{H} was measured at 3.5 V; the trigger current Iₜ₂ achieved only 0.6 A, or 3.6 mA/μm, close to the intrinsic Iₜ₂.

Curve “b” was measured using a protection device including an analogous nMOS transistor in series with a single large-area diode aligned along the transistor at distance d=5 μm between the n-well and the transistor fingers (distance d is designated 450 in FIG. 4). The holding voltage V_{H} dropped to 2.5 V; the trigger current Iₜ₂ achieved 1.3 A, or 8.3 mA/μm.

Curve “c” was measured using a protection device including an analogous nMOS transistor in series with a diode, which had its area divided into two halves and the halves positioned at opposing sides of the transistor at distance d=5 μm between each n-well and the transistor fingers. The holding voltage V_{H} dropped further to 1.9 V; the trigger current Iₜ₂ increased to 1.6 A, or 9.8 mA/μm.

Curve “d” was measured using a protection device including an analogous nMOS transistor in series with a diode, which had its area divided in to two halves and the halves positioned at opposing sides of the transistor at distance d=1.2 μm between each n-well and the transistor fingers. The holding voltage V_{H} dropped to 1.5 V; the trigger current Iₜ₂ increased to 1.9 A, or 12.1 mA/μm.

More data and experimental detail have been discussed in the following publications:

“The Optimization of Diode Isolated Grounded Gate nMOS for ESD Protection in Advanced CMOS Technologies”, Yen-Yi Lin, Vesselin Vassilev, and Charvaka Duvvury, International ESD Workshop, Lake Tahoe Calif., May 18, 2009.

### “Diode Isolated Concept for Low Voltage and High Voltage Protection Applications”, Yen-Yi Lin, Charvaka Duvvury, Agha Jahanzeb, and Vesselin Vassilev“, EOS/ESD Symposium Proceedings, pp. 322-328, 2009.

It is a technical advantage that the concept of dividing the diode area can be extended to applications, where the still finer slices of diode area are placed on three or four sides of the MOS transistor. It is another technical advantage that the concept can be applied to drain-extended MOS transistors.

There are numerous capacitances in a protection device; a couple of capacitances 570 are indicated in FIG. 5. Since the data rate, as driven by the Internet, of an electronic device is the higher, the lower device capacitance is, it remains a persistent goal of protection devices to keep their capacitance at a minimum. It is a technical advantage of the invention that the layout options between the diode and the transistor can be applied to maximize the discharge performance per unit capacitance.

It is a further technical advantage that by selecting the layout methodology, either the SCR discharge path or the diode-plus-npn transistor path can be applied for different pin applications. In addition, the holding voltage V_{H} can be tuned to make it useful for several specific applications, such as fail-safe inputs for products of Digital and Analog, High Voltage Analog, and USB.

On the other hand, for system level protection where SCR action is to be avoided, the proximity spacing between the diode well and the MOS transistor regions can be adjusted until only uniform diode-plus-npn conduction is achieved. Alternately, a portion of SCR conduction can be used as long as its holding voltage is selected to be >V_{DD}.

While this invention has been described in reference to illustrative embodiments, this description is not intended to be construed in a limiting sense. Various modifications and combinations of the illustrative embodiments, as well as other embodiments of the invention, will be apparent to persons skilled in the art upon reference to the description. As an example, the embodiments are effective in pMOS transistors as well as in nMOS transistors to create ESD protection. As another example, the substrate material may include silicon, silicon germanium, gallium arsenide and other semiconductor materials employed in manufacturing.

As yet another example, while the MOS transistor is preferably a multi-finger transistor, the concept of the invention can be applied to a methodology wherein the number of poly-fingers is reduced to control the trigger point. A MOS transistor with diode area portions positioned in proximity to its four sides may operate with fewer poly fingers while contacts, vias and metals still remain the same, resulting in higher trigger and holding voltages.

As yet another example, for system level ESD protection, where SCR action is to be avoided, the proximity spacing of the diode portions relative to the MOS transistor may be adjusted until only uniform npn conduction is achieved and the protection device functions only as a large efficient npn for substrate trigger with a relatively large holding voltage.

As yet another example, the MOS transistor can be divided to have interfacing diodes in multiple directions. An embodiment of this arrangement is depicted in FIG. 5. Another embodiment is schematically indicated in FIG. 7. The nMOS transistor is split into two halves, M/2; the diode D and the n-well are split three ways, D/3. By positioning the transistor and diode portions alternately while assuring the alignment between the diode regions and the respective transistor regions, and further by keeping a close proximity between the n-well portions and the transistor regions (designated 450 in FIG. 4 and “d” in FIG. 6), the ESD discharge current along the SCR path can be provided with a number of routes as indicated in FIG. 5 with the bulk substrate portions serving as heat sinks. Consequently, the embodiment allows a further cooling and postponement of the second breakdown onset and thus an additional increase of the trigger current Iₜ₂.

It is therefore intended that the appended claims encompass any such modifications or embodiments.

We claim:

1. A semiconductor device for protecting an integrated circuit input/output (I/O) pad against electrostatic discharge events, comprising:
a MOS transistor having at least one elongated source region and at least one elongated drain region in a substrate of first conductivity, the length of the source and drain regions oriented in a direction, the source tied to ground potential;
a diode having an area including at least one elongated anode region and at least one elongated cathode region in a well of opposite conductivity, the lengths of the anode and cathode regions oriented in the same direction as the transistor regions, the anode connected to the I/O pad and the cathode connected to the transistor drain; and
the diode area, including the anode and cathode regions and the well, divided normal to the direction of the length of the anode and cathode regions into two portions symmetrically positioned at opposite sides of the MOS transistor to allow a discharge current along the path of a parasitic silicon-controlled rectifier from the diode anode region through the well and the substrate to the transistor source region to utilize the substrate as a heat sink.

2. The device of claim 1 further including a positioning of the wells of opposite conductivity symmetrical relative to the MOS transistor sides.

3. The device of claim 2 further including a positioning of the wells of opposite conductivity relative to the respective MOS transistor regions at the closest proximity free of electrical shorts.

4. The device of claim 3 wherein the diode area portions are approximately equal with respect to size and shape.

5. The device of claim 1 wherein the MOS transistor has multi-finger source and drain regions oriented in a direction, and the diode has segmented elongated anode and cathode regions oriented in the same direction as the transistor regions and aligned with the respective transistor regions.

6. The device of claim 1 wherein the diode area is selected so that the diode is operable to have a low on-resistance and sufficient substrate pumping to turn on the MOS transistor.

7. The device of claim 1 further including additional divisions of the diode anode and cathode regions and the well into portions symmetrically positioned at more than two sides of the MOS transistor.

8. The device of claim 7 further including additional divisions into portions both of the MOS transistor source and drain regions and of the diode anode and cathode regions, the transistor and diode portions alternately positioned at close proximity between the well and the transistor regions, and aligned with regard to the respective diode and transistor regions.

9. The device of claim 1 further including a connection of the MOS transistor gate to ground potential.

10. A method for fabricating a semiconductor device for protecting an integrated circuit input/output (I/O) pad against electrostatic discharge events, comprising:
forming a MOS transistor having at least one elongated source region and at least one elongated drain region in a substrate of first conductivity, the length of the source and drain regions oriented in a direction;
connecting the source to ground potential;
forming a diode having an area including at least one elongated anode region and at least one elongated cathode region in a well of opposite conductivity, the lengths of the anode and cathode regions oriented in the same direction as the transistor regions;
dividing the diode area and the well normal to the lengths of the anode and cathode regions in two portions;
positioning the portions at opposite sides of the MOS transistor; and
connecting the anode portions to the I/O pad and the cathode portions to the transistor drain, thereby allowing a discharge current along the path of a parasitic silicon-controlled rectifier from the diode anode region through the well and the substrate to the transistor source region to utilize the substrate as a heat sink.

11. The method of claim 10 further including the step of positioning the diode portions symmetrically at opposite sides of the MOS transistor.

12. The method of claim 11 further including the step of positioning the diode portions at the closest proximity free of electrical shorts between the well and the transistor regions.

13. The method of claim 10 further including the step of aligning the directions of the diode anode and cathode regions with the directions of the respective transistor source and drain regions.

14. The method of claim 10 further including the step of selecting the diode area so that the diode is operable to have a low on-resistance and sufficient substrate pumping to turn on the MOS transistor.

15. The method of claim 10 further including the step of dividing the diode area in portions approximately equal with respect to size and shape.

16. The method of claim 10 further including the step of dividing the diode area in more than two portions and positioning the portions symmetrically at more than two sides of the MOS transistor.

17. The method of claim 10 further including the step of dividing into portions both the MOS transistor source and drain regions and the diode anode and cathode regions, positioning the transistor and diode portions alternately at close proximity between the well and the transistor regions, and aligning the respective diode and transistor regions.

18. The method of claim 10 further including the step of connecting the MOS transistor gate to ground potential.
